(19) United States
(12) Patent Application Publication
(10) Pub. No.: US 2024/0405186 A1
(43) Pub. Date: Dec. 5, 2024

(54) Display Apparatus

(71) Applicant: LG Display Co., Ltd., Seoul (KR)

(72) Inventor: Ju Han Kim, Paju-si (KR)

(21) Appl. No.: 18/636,968

(22) Filed: Apr. 16, 2024

(30) Foreign Application Priority Data
May 31, 2023 (KR) 10-2023-0070247

(51) Int. Cl. H01L 33/64; H01L 25/075; H01L 25/16; H01L 33/20; H01L 33/58

(52) U.S. Cl. CPC H01L 33/642; H01L 25/0753; H01L 25/167; H01L 33/20; H01L 33/58

(57) ABSTRACT

A display apparatus may include a display panel configured to display an image, a plate disposed on a rear surface of the display panel, a heat dissipation member disposed on a rear surface of the plate and having a first hole, and an adhesive member disposed between the plate and the heat dissipation member and having a second hole. The heat dissipation member may include a body part and a pattern part.

### CROSS-REFERENCE TO RELATED APPLICATION

This application claims priority to and the benefit of Republic of Korea Patent Application No. 10-2023-0070247, filed May 31, 2023, which is hereby incorporated by reference in its entirety.

### BACKGROUND

### Field

The present specification relates to a display apparatus, and more particularly to a display apparatus including a heat dissipation member.

### Discussion of Related Art

Modern display apparatuses that can display a variety of information and interact with the user viewing the display apparatuses require a variety sizes, shapes, and functions.

These display apparatuses include liquid crystal display apparatus (LCD), electrophoretic display apparatus (FPD), and light-emitting diode display apparatus (LED).

Improving the heat dissipation of a display apparatus has been a major research challenge, but a process of attaching a heat dissipation member to improve the heat dissipation may cause damage to a display panel. Accordingly, various considerations have been made for the improvement of the heat generation problem of the display apparatus while avoiding the damage to the display panel, but they are still insufficient, and development is urgently needed.

### SUMMARY

A problem to be solved by the present specification is to provide a display apparatus that is capable of minimizing or at least reducing stress concentration and stress-induced pressing on the display panel generated in a manner corresponding to loads applied to the heat dissipation member.

Another problem to be solved by the present specification is to provide a display apparatus that is capable of solving the problem of damage to the display panel during the process of attaching a heat dissipation member by configuring the heat dissipation member including a pattern.

Another problem to be solved by the present specification is to provide a display apparatus that is capable of avoiding the problem of damage to the display panel during the process of attaching the heat dissipation member by configuring the heat dissipation member having an elastic structure.

Problems of the present specification are not limited to the above-mentioned problems, and other problems which are not mentioned will be clearly understood by those skilled in the art from the following disclosure.

According to an embodiment of the present specification, a display apparatus may include a display panel configured to display an image, a plate disposed on a rear surface of the display panel, a heat dissipation member disposed on a rear surface of the plate and having a first hole, and an adhesive member disposed between the plate and the heat dissipation member and having a second hole. The heat dissipation member may include a body part and a pattern part.

According to an embodiment of the present specification, the display apparatus may include the heat dissipation member, thereby solving the problem of heat generation caused by the operation of the display apparatus.

According to an embodiment of the present specification, the display apparatus may minimize or at least reduce stress concentration and stress-induced pressing on the display panel generated in a manner corresponding to loads applied to the heat dissipation member.

According to an embodiment of the present specification, the display apparatus may include the heat dissipation member having an elastic structure, such as a pattern or a step, thereby minimizing or at least reducing stress concentration and stress-induced pressing on the display panel in a manner corresponding to loads applied to the display panel during the process of attaching the heat dissipation member.

According to an embodiment of the present specification, the display apparatus may improve the problem of heat generation, thereby reducing power consumption of the display apparatus and/or providing a low-power display apparatus.

The effects of this specification are not limited to the above effects, and other effects, which are not mentioned herein, will be obvious to those skilled in the art from the following description.

### BRIEF DESCRIPTION OF THE DRAWINGS

The above and other objects, features, and advantages of the present specification will become more apparent to those of ordinary skill in the art by describing exemplary embodiments thereof in detail with reference to the attached drawings, in which:

FIG. 1 is a diagram illustrating a rear surface of a display apparatus according to an embodiment of the present specification;

FIG. 2 is a cross-sectional view taken along line I-I′ of FIG. 1, according to an embodiment of the present specification;

FIG. 3 is an enlarged view of the area A shown in FIG. 1, according to an embodiment of the present specification;

FIG. 4 is a cross-sectional view taken along line II-II′ of FIG. 3, according to an embodiment of the present specification;

FIG. 5 is a plan view illustrating a process of attaching a heat dissipation member according to an embodiment of the present specification;

FIG. 6A to 6D are diagrams illustrating a process of attaching a heat dissipation member according to an embodiment of the present specification;

FIG. 7 is a cross-sectional view of a display apparatus including a heat dissipation member according to another embodiment of the present specification;

FIG. 8 is a cross-sectional view of a display apparatus including a heat dissipation member according to another embodiment of the present specification;

FIG. 9 is a cross-sectional view of a display panel according to an embodiment of the present specification;

FIG. 10 is a cross-sectional view of a light-emitting unit according to an embodiment of the present specification.

### DETAILED DESCRIPTION

Advantages and features of the present specification, and methods of achieving them will become apparent with reference to embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted. When ‘including,’ ‘having,’ ‘comprising,’ and the like mentioned in the present specification are used, other parts may be added unless ‘only’ is used.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

When describing a temporal contextual relationship is described, such as “after,” “following,” “next to,” or “before,” it may also include non-contiguous cases unless “immediately” or “directly” is used.

The first, the second, and so on are used to describe various components, but these components are not limited by these terms. These terms are used only to distinguish one component from another. Therefore, the first component referred to below may be a second component within the technical spirit of the present disclosure.

Terms such as first, second, A, B, (a), (b), and the like may be used to describe elements of the embodiments of the present specification. Such terms are intended only to distinguish one component from another and are not intended to define the nature, sequence, order, or number of such components. When a component is described as “connected,” “coupled,” or “attached” to another component, it is to be understood that the component may be directly connected or attached to the other component, but that there may also be other components “interposed” between the respective components which may be indirectly connected or attached where not specifically stated.

It should be understood that the term “at least one” includes all possible combinations of one or more related components. For example, the meaning of “at least one of the first, second, and third components” includes not only the first, second, or third component, but also any combination of two or more of the first, second, and third components.

As used herein, “an apparatus” may include a display apparatus such as a liquid crystal module (LCM), or an organic light-emitting diode (OLED) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

Accordingly, the apparatus as described herein may include a display apparatus itself, such as the LCM, the OLED module, as well as a set device, which is an application product or an end user device that includes the LCM, and the QLED module.

In some embodiments, the LCM, and the OLED module comprising the display panel and the driver may be expressed as a “display apparatus”, while the electronic device as a finished product including the LCM, and the OLED module may be expressed as a “set device”. For example, the display apparatus may include a liquid crystal display (LCD) panel, or an organic light-emitting diode (OLED) display panel and a source PCB that is a control part for driving the display panel. The set device may further include a set PCB that is a set control part electrically connected to the source PCB to control the entire set device.

The display panel used in an embodiment of the present specification may be any type of display panel, including, but not limited to, liquid crystal display panels, organic light-emitting diode (OLED) display panels, and electroluminescent display panels. The display panel applicable to the display apparatus according to an embodiment of the present specification is not limited to the shape or size thereof.

Each of the features of various embodiments described herein may be coupled or combined with one another in whole or in part, and may be technologically interlocked and operated in various ways, and each of the embodiments may be carried out independently or in conjunction with one another.

Hereinafter, embodiments of the present specification are illustrated by way of the accompanying drawings and examples. The dimensions of the components shown in the drawings are to scale for illustrative purposes only and are not to scale with the actual components.

The various embodiments of the present specification will be described in detail below with reference to the accompanying drawings.

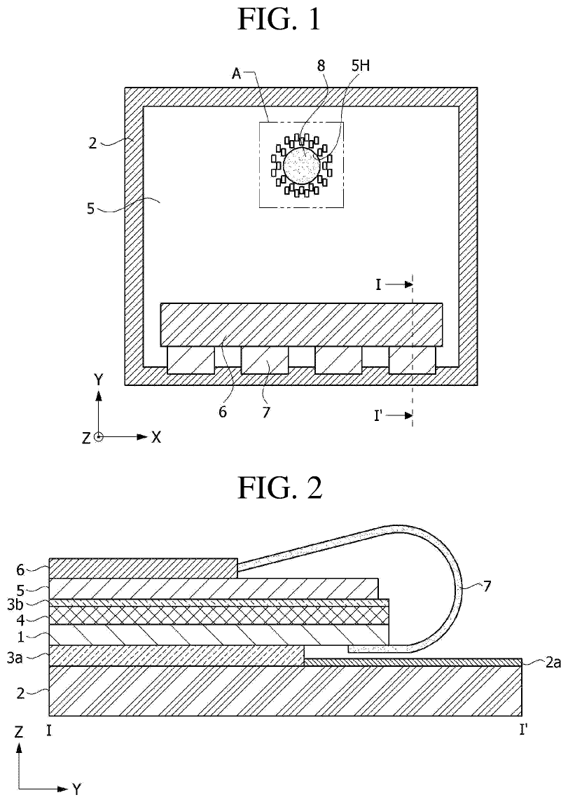

FIG. 1 is a view illustrating the rear surface of a display apparatus according to an embodiment of the present specification.

FIG. 2 is a cross-sectional view taken along line I-I′ of FIG. 1, according to an embodiment of the present specification.

Referring to FIGS. 1 and 2, a display apparatus according to an embodiment of the present specification may include a display panel 1 and a heat dissipation member 5.

The display panel 1 of the display apparatus according to an embodiment of the present specification may be a panel having a rectangular structure with a length in the X-axis direction, a width in the Y-axis direction, and a thickness in the Z-axis direction. Pixels disposed on the display panel 1 include a plurality of sub-pixels of different colors. Here, the width and length of the display panel 1 may be set to different design values depending on the area of application of the display apparatus. In addition, the X-axis direction may be a longitudinal direction or a horizontal direction, the Y-axis direction may be a width direction or a vertical direction, and the Z-axis direction may be an up-down direction or a thickness direction. In addition, the X-axis direction, Y-axis direction, and Z-axis direction may be perpendicular to each other, but may also include different directions that are not perpendicular to each other. Accordingly, each of the X-axis direction, Y-axis direction, and Z-axis direction may be described as one of a first direction, a second direction, and a third direction. In addition, the plane extending in the X-axis direction and the Y-axis direction may be a horizontal plane.

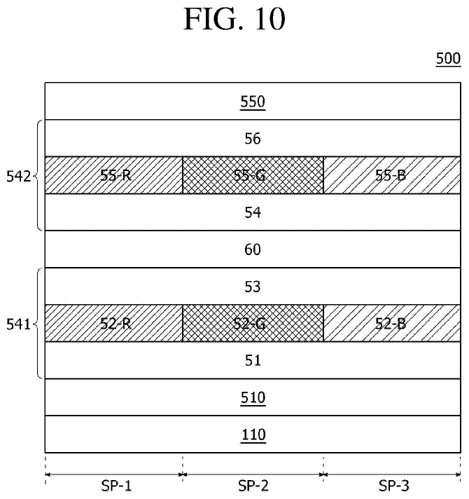

The display panel 1 in the display apparatus may display an image or a video. The display panel according to the present specification may include a light-emitting diode (LED). The components of the display panel 1 will be described later with reference to FIGS. 9 and 10.

A front member 2 may be disposed on the front surface of the display panel 1. The front member 2 may protect the display panel 1 and other components located on the lower or upper surface of the front member from external impacts, moisture, and heat. The front member 2 may be made of a material having an impact resistance and light transmittance. For example, the front member 2 may be a substrate made of glass, or a film made of a plastic material such as, but not limited to, polymethylmethacrylate (PMMA), polyimide (PI), polyethylene terephthalate (PET).

The front member 2 may also be referred to as various other names, such as a cover window, a window cover, or a cover glass, and embodiments of the present specification are not limited thereto.

The front member 2 may be formed to be transparent so that light emitted from the display panel 1 is transmitted to the outside of the display apparatus and an image provided by the display apparatus is viewed by a user.

A blocking portion 2a of the front member 2 may be formed to be opaque so that the wirings, driving circuits, and various components formed on the lower or upper surface of the front member 2 in the display apparatus are not visible to the user.

The blocking portion 2a may contain pigments, dyes, and light-shielding materials such as carbon black. For example, the blocking portion 2a may be formed or coated with black ink on the front member 2. Alternatively, the blocking portion 2a may be attached to the front member 2 with a separate component formed at the rear edge of the front member 2.

The blocking portion 2a may be disposed at the end of the front member 2. The blocking portion 2a may be disposed to surround a portion of the end of the display panel 1. The blocking portion 2a may be disposed to overlap a portion of one or more of the display panel 1, a plate 4, the heat dissipation member 5, a printed circuit board 6, or a flexible film 7.

An adhesive member may be disposed between the display panel 1 and the front member 2. For example, a first adhesive member 3a may be disposed between the display panel 1 and the front member 2. The first adhesive member 3a may be made of a material having adhesiveness for fixing the front member 2 to the front surface of the display panel 1. The first adhesive member 3a may be disposed along an edge (or a border) of the display panel 1 and along an edge (or a border) of the front member 2. The first adhesive member 3a may have a shape corresponding to an edge (or a border) of the display panel 1. For example, the first adhesive member 3a may be configured in a shape of a picture frame corresponding to the edge (or a border) of the display panel 1, but embodiments of the present specification are not limited thereto. For example, the first adhesive member 3a may be an adhesive foam tape, a double-sided tape, a double-sided foam tape, or a double-sided foam pad, but embodiments of the present specification are not limited to those described above.

The plate 4 may be disposed on the rear surface of the display panel 1. The plate 4 may support and protect the display panel 1 on the rear surface of the display panel 1. The plate 4 has a shape corresponding to the planar shape of the display panel 1 and may cover the display panel 1. The plate 4 may be made of a material that is rigid and has high thermal conductivity. For example, the plate 4 may be made of a metal material such as aluminum (Al), copper (Cu), zinc (Zn), silver (Ag), gold (Au), iron (Fe), stainless steel (SUS), or Invar, or a material such as plastic, and embodiments of the present specification are not limited thereto. For example, the plate 4 may be a cover bottom, and embodiments of the present specification are not limited thereto. The plate 4 may further include one or more openings.

An adhesive member may also be disposed between the display panel 1 and the plate 4.

The heat dissipation member 5 may be disposed on the rear surface of the plate 4. Alternatively, the heat dissipation member 5 may be disposed between the display panel 1 and the printed circuit board 6 or between the plate 4 and the printed circuit board 6.

The heat dissipation member 5 may dissipate heat transferred from the display panel 1. The heat dissipation member 5 may include a material having good thermal conductivity, and the heat dissipation member 5 may dissipate heat transferred from the display panel by distributing the heat. For example, the heat dissipation member 5 may include at least one or more of the following materials: aluminum (Al), copper (Cu), copper foam, or graphite; an alloy material thereof, or a bonded structure thereof, and embodiments of the present specification are not limited thereto.

Further, the heat dissipation member 5 may prevent the printed circuit board 6 and the display panel 1 from being in direct contact, whereby the heat from the printed circuit board 6 may be minimized or at least reduced from being concentrated in a particular area of the display panel 1. The printed circuit board 6 includes a plurality of parts disposed thereon, and among the plurality of parts, there may be some driving chips that generate a large amount of heat. The heat dissipation member 5 may distribute the heat generated from some driving chips of the printed circuit board 6 to the entirety of the heat dissipation member 5 so that the heat is not concentrated in some areas of the display panel 1 adjacent to the driving chips, thereby reducing the overall temperature deviation of the display panel 1.

The heat dissipation member 5 may include a hole passing through a portion of the heat dissipation member 5 at one side of the display apparatus for positioning an optical device 8. For example, the heat dissipation member 5 may include a first hole 5H. The first hole 5H may be formed through the heat dissipation member 5 to secure a space in which the optical device is disposed.

The optical device 8 may be disposed inside the first hole 5H of the heat dissipation member 5. For example, the optical device 8 may include a camera or an optical sensor (or a luminance sensor), such as a proximity sensor, an infrared sensor, an ultraviolet sensor, and the like.

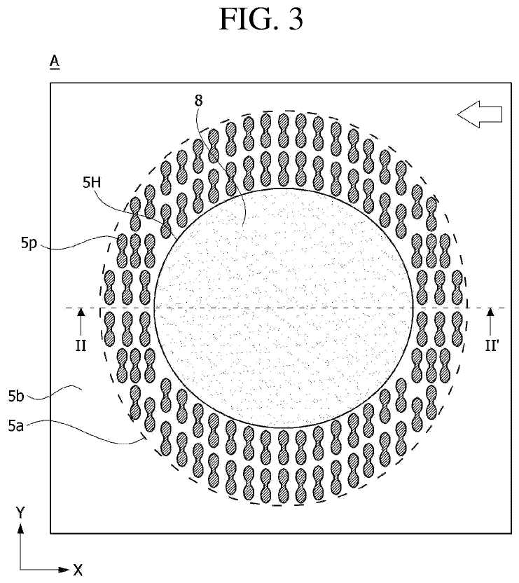

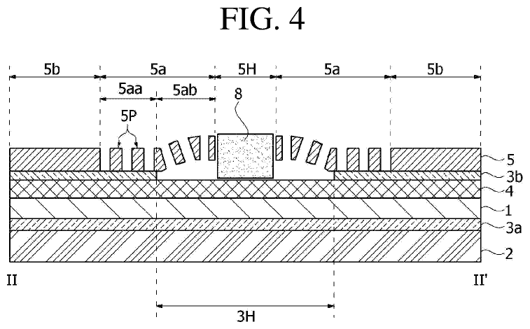

The heat dissipation member 5 and the first hole 5H will be described later with reference to FIGS. 3 and 4.

An adhesive member may be disposed between the plate 4 and the heat dissipation member 5. For example, a second adhesive member 3b may be disposed between the plate 4 and the heat dissipation member 5. The second adhesive member 3b may be made of a material having adhesiveness to secure the plate 4 to the front surface of the heat dissipation member 5. The second adhesive member 3b may be disposed on the rear surface of the plate 4 or on the front surface of the heat dissipation member 5, but embodiments of the present specification are not limited thereto. For example, the second adhesive member 3b may be, but is not limited to, an adhesive foam tape, a double-sided tape, a double-sided foam tape, or a double-sided foam pad.

The second adhesive member 3b may include a hole. For example, the second adhesive member 3b may include a second hole 3H.

The second adhesive member 3b and the second hole 3H will be described later with reference to FIGS. 3 and 4.

The printed circuit board 6 may be disposed on the rear surface of the heat dissipation member 5 or the plate 4. Referring to FIG. 1, the printed circuit board 6 may be disposed on the other side of the display apparatus so as not to overlap the first hole 5H of the heat dissipation member 5.

The printed circuit board 6 may be a part that supplies signals to the driving IC. A variety of components for supplying different signals to the driving IC may be disposed on the printed circuit board 6.

The flexible film 7 may be bonded to one surface of the printed circuit board 6. The flexible film 7 may be provided in plural. The flexible film 7 may be a film in which various components are arranged on a flexible base film to supply signals to the sub-pixels and the driving components. The flexible film 7 may be electrically connected to the display panel 1.

A driving IC, such as a gate driver IC or a data driver IC, may be disposed on the flexible film 7, and embodiments of the present specification are not limited thereto. The driving IC may be a component that processes data for displaying an image and a driving signal to process the data. Depending on how it is mounted, the driving IC may be arranged in a manner such as a chip on glass (COG), a chip on film (COF), or a tape carrier package (TCP), and embodiments of the present specification are not limited thereto. For ease of illustration, the driving IC is described as being chip-on-film with the driving IC mounted on a plurality of flexible films 7, but embodiments of the present specification are not limited thereto.

Although four flexible films 7 and one printed circuit board 6 are shown in FIG. 1, the number of the plurality of flexible films 7 and printed circuit boards 6 may vary depending on the design, and embodiments of the present specification are not limited thereto.

A cover shield may be further disposed on the rear surface of the printed circuit board 6 or the heat dissipation member 5. The cover shield may protect the printed circuit board 6 or the heat dissipation member 5 from external impact. The cover shield may be made of a rigid material and may protect the printed circuit board 6 or the heat dissipation member 5, but embodiments of the present specification are not limited thereto. The cover shield may be disposed to cover the printed circuit board 6 or the heat dissipation member 5. The cover shield may be a shield member or a protective member, and embodiments of the present specification are not limited thereto.

Hereinafter, with reference to FIGS. 3 and 4, the heat dissipation member of the present specification will be described in detail.

FIG. 3 is an enlarged view of the area A shown in FIG. 1, according to an embodiment of the present specification.

FIG. 4 is a cross-sectional view taken along line II-II′ of FIG. 3, according to an embodiment of the present specification.

Referring to FIGS. 3 and 4, the heat dissipation member according to embodiment of the present specification may include a pattern.

Referring to FIG. 3, the heat dissipation member 5 may include a first hole 5H, a pattern part 5a, and a body part 5b.

The first hole 5H may be a hollow space in which the optical device 8 is disposed. The first hole 5H may be disposed in the pattern part 5a.

The first hole 5H may be formed by cutting a portion of the heat dissipation member 5 to position the optical device 8 within the heat dissipation member 5. Although the first hole 5H is shown as circular in the drawings of the present specification, the first hole 5H may be notched or otherwise shaped, and embodiments of the present specification are not limited thereto.

The heat dissipation member 5 may include the pattern part 5a surrounding the first hole 5H. The pattern part 5a may surround the optical device 8 disposed in the first hole 5H. By cutting a portion of the pattern part 5a to form the first hole 5H, the pattern part 5a may have an inside surface forming the first hole 5H. The inside surface may be a surface disposed to face the optical device 8, which may be disposed adjacent to the optical device 8. Here, the term “adjacent” may include being in contact or separated by a predetermined distance.

The pattern part 5a may be adjacent to the first hole 5H and may be disposed outwardly of the first hole 5H with respect to the center of the first hole 5H. Further, the pattern part 5a may be disposed between the first hole 5H and the body part 5b.

The pattern part 5a may include a predetermined pattern 5p. The pattern 5p may be a metallic pattern, and it may be further gradually protruded from the second adhesive member 3b in the direction of the optical device 8. A plurality of patterns 5p may be configured and disposed to surround the optical device 8, and embodiments of the present specification are not limited thereto. For example, the pattern 5p may include a variety of patterns, such as a mesh or a grid, and embodiments herein are not limited thereto.

When attaching the heat dissipation member 5, the heat dissipation member 5 may be attached to the rear surface of the display panel using a roller. When the roller moves the area where the pattern part 5a is disposed, the pattern 5p may be contracted or relaxed to prevent damage to the display panel.

If the heat dissipation member 5 is attached, a problem of stress concentration on the display panel may occur in response to the load applied to the heat dissipation member by the roller may occur. This may cause a problem where the display panel is pressed, for example, a problem where the display panel is damaged, such as a stain defect. For example, the movement of the roller may cause an instantaneous load to be concentrated in the peripheral area where the hole of the heat dissipation member is located, thus worsening the problem.

Accordingly, an embodiment of the present specification may improve the problem of the occurrence of the stain on the display panel by changing an area where the second adhesive member 3b used to attach the heat dissipation member 5 is located and the configuration or structure of the heat dissipation member 5.

An embodiment of the present specification may prevent or minimize or at least reduce the load applied to the heat dissipation member 5 around the first hole 5H from being directly applied to the display panel 1 by the arrangement of the second adhesive member 3b, a load absorbing structure such as a pattern, an elastic structure using elastic resilience, and the like.

Depending on whether the second adhesive member 3b is placed or not, for example, depending on whether the second adhesive member 3b is present or not, the pattern part 5a may include a first pattern area 5aa in contact with the second adhesive member 3b, and a second pattern area 5ab not in contact with the second adhesive member 3b. Here, the first pattern area 5aa may be a first area or a contact area. The second pattern area 5ab may be a second area, a non-contact area, or a protruding area, and it may be an elastic area, a bending area, or a step area when an elastic structure having a shape such as a step or a bend is formed.

A portion of the load applied to the display panel 1 may be absorbed by the second adhesive member 3b, which is disposed below the first pattern area 5aa.

The second pattern area 5ab may be an area that does not overlap the second adhesive member 3b, and therefore the second pattern area 5ab may be spaced apart from the rear surface of the heat dissipation member 5 by a predetermined interval. Accordingly, the load applied to the second pattern area 5ab may not be applied directly to the display panel 1 thanks to the interval. The second pattern area 5ab may contact the rear surface of the display panel 1 according to the amount of deformation of the second pattern area 5ab under the load applied to the second pattern area 5ab, but such contact may be prevented by the material of the heat dissipation member 5, and the material and the thickness of the second adhesive member 3b. Further, the contact of the second pattern area 5ab with the display panel 1 may be blocked by the elastic structure of the second pattern area 5ab to be described later.

Further, the pattern part 5a may minimize or at least reduce the load applied to the display panel 1 by the load on the heat dissipation member 5 by using an elastic absorbing structure which is contracted by the load and relaxed by the load release. The pattern part 5a may absorb some of the load applied to the pattern part 5a and transferred to the display panel 1 by using a plurality of patterns 5p implementing the shape of a mesh or a grid. For example, as the roller moves, a load is applied to the pattern 5p by the pressure of the roller, and the load applied to the pattern 5p causes the pattern 5p to contract. Subsequently, as the roller continues to move, the pressure of the roller is released, thereby releasing the load on the pattern 5p and relaxing the pattern 5p. Accordingly, the load absorbing structure implemented by the pattern 5p may minimize or reduce the load applied to the display panel 1.

For example, the pattern part 5a may prevent or minimize the load applied to the heat dissipation member 5 from being applied to the display panel 1 by using an elastic structure with elastic restoring force.

The heat dissipation member 5 may be formed of a material having a predetermined rigidity and may realize an elastic structure by bending the second pattern portion 5ab. Accordingly, even if a predetermined load is applied to the elastic structure, it is possible to prevent or minimize or at least reduce the load from being applied to the display panel 1 by the elastic restoring force of the elastic structure.

As shown in FIG. 4, the second pattern area 5ab extending from the first pattern area 5aa may be bent so as to be spaced apart by an interval from the rear surface of the display panel 1. And, the end portion of the second pattern area 5ab may be further prevented from contacting the rear surface of the display panel 1 by the interval. For example, the interval on one side of the second pattern area 5ab may be larger than the interval on the other side. Here, one side of the second pattern area 5ab may represent an end portion of the second pattern area 5ab that is adjacent to the optical device 8, and the other side of the second pattern area 5ab may represent an area that is connected to the first pattern area 5aa. For example, since the first pattern area 5aa may be spaced apart by a first interval with respect to the rear surface of the display panel 1 and the end portion of the second pattern area 5ab may be spaced apart by a second interval larger than the first interval, the end portion of the second pattern area 5ab may not be in contact with the rear surface of the display panel 1 due to the second interval and the elastic force even if a predetermined load is applied to the end of the second pattern area 5ab.

Although the display apparatus according to the present specification is illustrated in FIG. 4 with a space formed between the second pattern area 5ab and the rear surface of the display panel 1, embodiments of the present specification are not limited thereto. For example, the diameter of the first hole 5H and the diameter of the second hole 3H may be formed to be the same, so that the second adhesive member 3b may be disposed between the second pattern area 5ab and the rear surface of the display panel 1. The end portion of the second pattern area 5ab may be bent to be away from the second adhesive member 3b. Therefore, when the second adhesive member 3b is disposed between the second pattern area 5ab and the rear surface of the display panel 1, even if a predetermined load is applied to the second pattern area 5ab, the second adhesive member 3b may first contact the end portion of the second pattern area 5ab, thereby preventing the stain such as scratches from occurring on the display panel 1.

Referring to FIG. 4, the heat dissipation member 5 may include the body part 5b surrounding the pattern part 5a. The body part 5b may be adjacent to the pattern part 5a and may be located outside the pattern part 5a. The body part 5b may be formed in a flat state, and the front surface of the body part 5b may be disposed on the display panel 1.

The heat dissipation member 5 may include the pattern part 5a surrounded by the body part 5b. The pattern part 5a may be disposed between the first hole 5H of the heat dissipation member 5 and the body part 5b of the heat dissipation member 5. The pattern part 5a may extend from the body part 5b and may have a predetermined pattern 5p arranged thereon. Referring to FIG. 4, the pattern 5p may be at least partially adhered to the second adhesive member 3b, or the pattern 5p may not be at least partially adhered to the second adhesive member 3b.

The pattern part 5a may further include a protrusion protruding from the second adhesive member 3b. The protrusion may correspond to the second pattern area 5ab. Further, the protrusion may overlap the second hole 3H of the second adhesive member 3b. The protrusion may be configured to be at a predetermined angle with the second adhesive member 3b. For example, the angle between the protrusion and the second adhesive member 3b may be 95 degrees or more and 179 degrees or less. The pattern part 5a may have a step or a curve due to the angle of the protrusion.

The heat dissipation member 5 may include the first hole 5H. The second adhesive member 3b may be disposed between the plate 4 and the heat dissipation member 5. The second adhesive member 3b may include the second hole 3H.

The first hole 5H of the heat dissipation member 5 and the second hole 3H of the second adhesive member 3b may overlap. The diameter of the first hole 5H of the heat dissipation member 5 may be smaller than the diameter of the second hole 3H of the second adhesive member 3b.

The pattern part 5a or the pattern 5p of the heat dissipation member may overlap at least partially with the second adhesive member 3b.

The pattern part 5a or the pattern 5p of the heat dissipation member may further protrude from the second adhesive member 3b. For example, the pattern part 5a or the pattern 5p of the heat dissipation member may further include a protrusion. The protrusion may overlap the second hole 3H of the second adhesive member 3b.

The angle formed by the protrusion PP and the second adhesive member 3b may be 95 degrees or more and 179 degrees or less. Here, the angle may be an angle formed by the rear surface of the first pattern area 5aa and the rear surface of the second pattern area 5ab, and may be an obtuse angle.

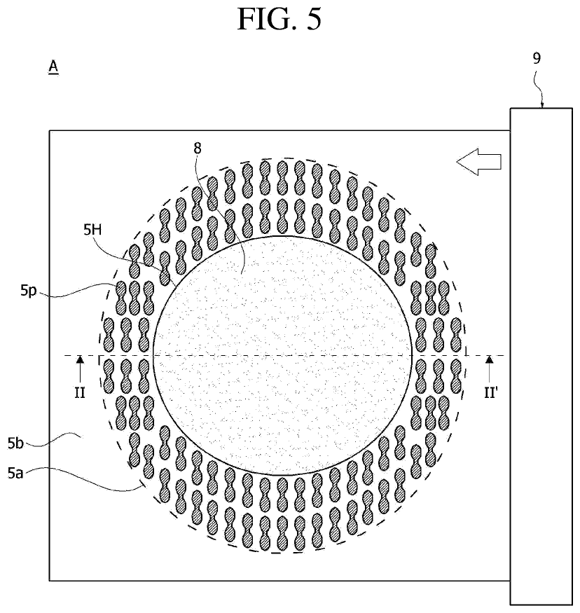

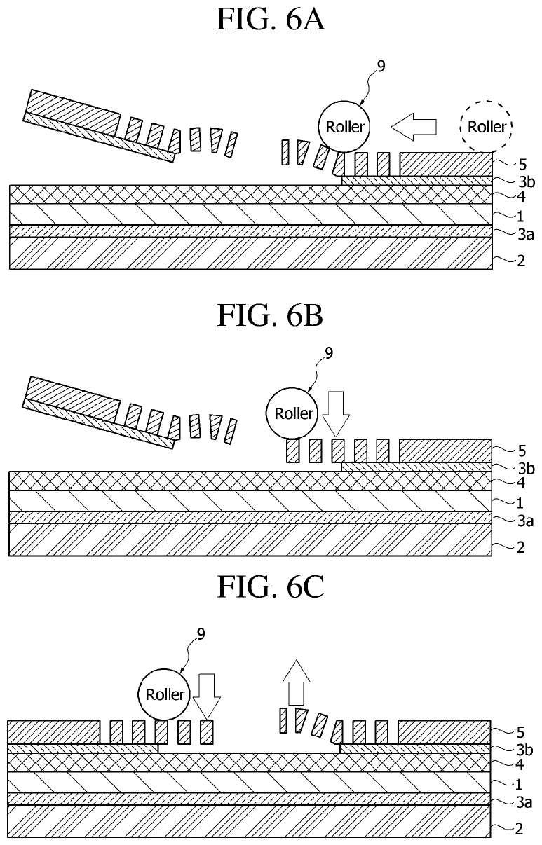

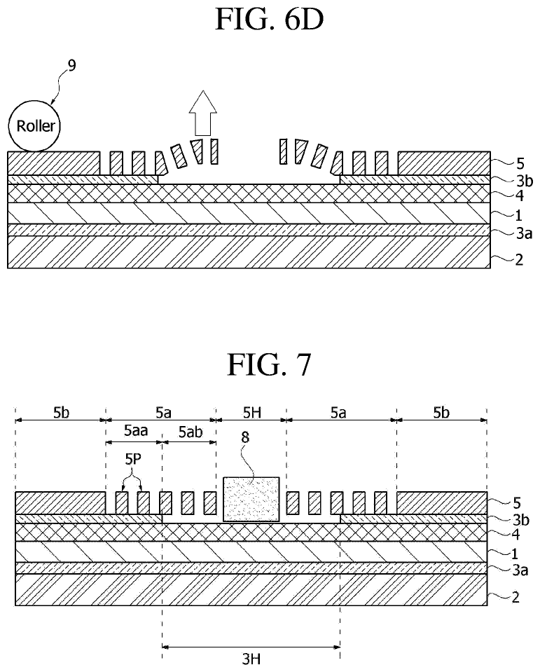

A process of attaching the heat dissipation member and a shape of the contraction or relaxation of the pattern 5p will be discussed in detail with reference to FIG. 5 and FIGS. 6A to 6D.

The optical device 8 may be disposed in the first hole 5H of the heat dissipation member 5 and the second hole 3H of the second adhesive member 3b. The first hole 5H of the heat dissipation member 5 may be disposed to surround the periphery of the optical device 8. For example, the first hole 5H of the heat dissipation member 5 may be disposed to surround the periphery of the optical device 8 so that the optical device 8 may be fixed. For example, the end portion of the second pattern area 5ab may guide the disposition of the optical device 8. And, the end portion of the second pattern area 5ab may be disposed adjacent to the optical device 8 so that the optical device 8 may be fixed to the end portion of the second pattern area 5ab by an adhesive member or the like.

For example, the optical device 8 may be disposed on the plate and may be surrounded by the pattern part 5a of the heat dissipation member 5.

FIG. 5 is a plan view illustrating a process of attaching a heat dissipation member according to an embodiment of the present specification.

FIG. 6A to 6D are diagrams illustrating a process of attaching a heat dissipation member according to an embodiment of the present specification.

Referring to FIG. 5, the heat dissipation member of the display apparatus of the present specification may be attached to the rear surface of the display panel 1 using a roller 9. For example, the second adhesive member 3b may be formed on the entire surface of the rear surface of the display panel 1, except for the area where the second hole 3H is disposed, and the heat dissipation member 5 may be attached using the roller 9. When the heat dissipation member 5 is attached using the roller 9, the heat dissipation member 5 may be uniformly attached to the rear surface of the display panel 1 without any problems of non-attachment or non-compression that may occur between the heat dissipation member 5 and the display panel 1 during the attachment process. The heat dissipation member 5 may be attached to the entire surface of the display panel 1, except for an area where the first hole 5H is disposed.

FIG. 6A is a diagram showing that the roller 9 moves from the body part on one side of the heat dissipation member to the pattern part. FIG. 6B is a diagram showing the roller 9 moving on the pattern part of the heat dissipation member.

Referring to FIG. 6B, even if the heat dissipation member 5 is pressed under load by the roller 9, there is no problem of the stain caused by the display panel 1 being pressed or compressed by the pattern 5p and the angle of the heat dissipation member 5.

FIG. 6C is a diagram showing that the roller 9 continues to move through the first hole 5H of the heat dissipation member 5 to the pattern part 5a on the other side. The pattern 5p on one side of the heat dissipation member 5 under the load as shown in FIG. 6B may be restored to its original shape by an elastic restoring force. The pattern part 5a disposed on the other side may be pressed under the load.

FIG. 6D is a diagram showing that the roller 9 continues to move from the pattern part 5a on the other side to the body part 5b. Referring to FIG. 6D, when the roller 9 moves from the pattern part 5A to the body part 5b, the pattern 5p may be restored to its original shape by elastic restoring force. There is no problem of the stain caused by the display panel 1 being pressed or compressed by the pattern 5p and the angle of the heat dissipation member 5.

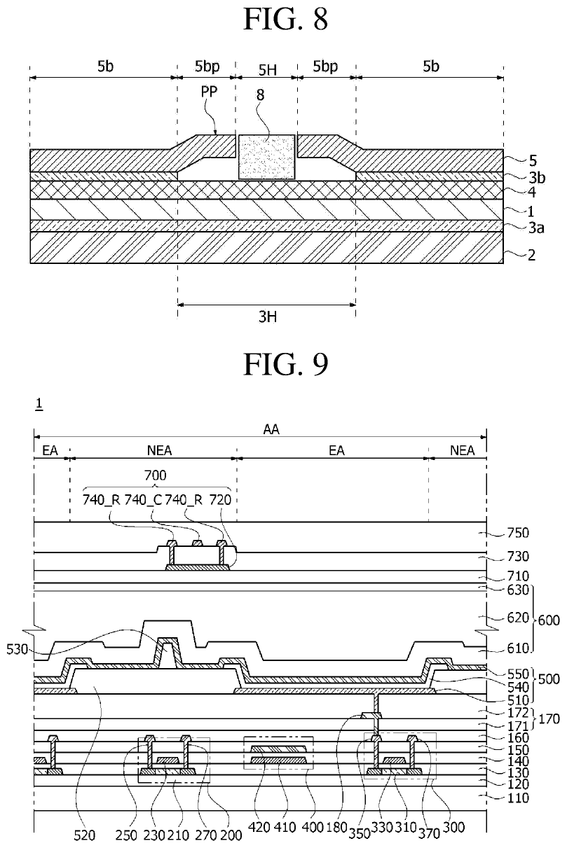

Hereinafter, other embodiments of the present specification will be described in detail with reference to FIGS. 7 and 8.

FIGS. 7 and 8 are substantially the same as the display apparatus of FIG. 4 except for the configuration of the heat dissipation member 5, and therefore redundant descriptions may be omitted or abbreviated.

FIG. 7 is a cross-sectional view of a display apparatus including a heat dissipation member according to another embodiment of the present specification.

Referring to FIG. 7, the heat dissipation member 5 has the pattern 5P of the pattern part 5a whose configuration and protrusion are the same as FIG. 4, wherein the pattern part 5a or the pattern 5p may be flat without an angle.

The pattern 5p is composed of a plurality of patterns, and the mesh pattern has elasticity, resulting in the load applied to the pattern part 5a being buffered even when the pattern is attached using the roller 9, thereby solving the problem of the occurrence of the stain on the display panel 1 when pressing the display panel 1.

FIG. 8 is a cross-sectional view of a display apparatus including a heat dissipation member according to another embodiment of the present specification.

Referring to FIG. 8, in the heat dissipation member 5, the pattern part 5a is changed to the body protrusion part 5bp as compared to FIG. 4, and the angle is the same, but the pattern may be excluded. The body protrusion part 5bp may be an area corresponding to the second pattern area 5ab from which the pattern 5p is deleted.

The heat dissipation member 5 may include a body part 5b and a protrusion part PP extending from the body part 5b and having a first hole 5H.

Since the protrusion part PP has a predetermined angle, it is possible to solve the problem of the stain on the display panel 1 when the display panel 1 is pressed due to load distribution, even when it is attached using the roller 9.

The angle between the body part 5b and the protrusion part PP may be greater than or equal to 95 degrees and less than or equal to 179 degrees. If the angle between the body part 5b and the protrusion part PP is less than 95 degrees, the height of the protrusion part PP may be high, which may cause a problem in manufacturing a thin device, and if the angle between the body part 5b and the protrusion part PP is greater than 179 degrees, the display panel may be stressed during a rolling process of the roller 9, which may cause the stain.

The display apparatus according to an embodiment of the present specification may further include the optical device 8 disposed within the first hole 5H.

FIG. 9 is a cross-sectional view of a display panel according to an embodiment of the present specification.

FIG. 9 is a diagram illustrating a portion of the cross-sectional structure of a sub-pixel positioned in the display area where the image is displayed. In the sub-pixel, a light-emitting device layer 500 for displaying an image, and a plurality of first thin-film transistors 200 and second thin-film transistors 300 for driving the light-emitting device layer 500 may be disposed.

The substrate 110 may support various components of the display apparatus. The substrate 110 may be made of glass, or a plastic material having flexibility.

For example, the substrate 110 may be formed of at least one or more of, but not limited to, polyimide (PI), polymethylmethacrylate (PMMA), polyethylene terephthlate (PET), polyethersulfone, or polycarbonate (PC).

When the substrate 110 is made of polyimide, it may be formed of two layers of polyimide. An additional inorganic film may be disposed between the two polyimide layers.

The elements and the functional layers formed on the substrate 110 may also be referred to as a concept including, but not limited to, such as a switching thin-film transistor, a driving thin-film transistor connected to the switching thin-film transistor, an organic light-emitting element connected to the driving thin-film transistor, a protective layer, and the like.

The first insulating layer 120 may be disposed over the entirety of the substrate 110. For example, the first insulating layer 120 may be disposed over the entire surface of the substrate 110.

The first insulating layer 120 may be formed on the substrate 110 to block material within the substrate 110 from migrating to the thin-film transistor or the semiconductor layer during a deposition process.

The first insulating layer 120 may be formed of an insulating inorganic material, such as, but not limited to, silicon nitride (SiNx) or silicon oxide (SiOx), and may also be formed of an insulating organic material.

The first insulating layer 120 may be made of a single layer of silicon nitride (SiNx) or silicon oxide (SiOx), or multiple layers thereof, but embodiments of the present specification are not limited thereto. When the first insulating layer 120 is multi-layered, it may be formed by alternating layers of silicon oxide (SiOx) and silicon nitride (SiNx), but embodiments of the present specification are not limited thereto.

The first insulating layer 120 may be a buffer layer or a first buffer layer, and embodiments of the present specification are not limited thereto.

The first insulating layer 120 may be omitted depending on the type and material of the substrate 110, the structure and type of the thin-film transistor, and the like.

The first thin-film transistor 200 and the second thin-film transistor 300 may be disposed on the first insulating layer 120. The first thin-film transistor 200 may be a switching thin-film transistor, and the second thin-film transistor 300 may be a driving thin-film transistor, and embodiments of the present specification are not limited thereto.

The first thin-film transistor 200 may include a first semiconductor layer 210, a first gate electrode 230, a first source electrode 250, and a first drain electrode 270. The second thin-film transistor 300 may include a second semiconductor layer 310, a second gate electrode 330, a second source electrode 350, and a second drain electrode 370.

For convenience of explanation, only two of the various thin-film transistors are shown, but other thin-film transistors may be included in the display apparatus. Also, for convenience of explanation, the thin-film transistor is described as having an upper gate (or top gate) structure in which the gate electrode constituting the thin film transistor is located at the top of the semiconductor layer, but is not limited to this structure and may be implemented in other structures, such as a lower gate (or bottom gate) structure in which the gate electrode is located at the bottom of the semiconductor layer, or a double gate structure in which the gate electrode is located at both the top and bottom of the semiconductor layer.

The first semiconductor layer 210 of the first thin-film transistor 200 and the second semiconductor layer 310 of the second thin-film transistor 300 may be disposed on the first insulating layer 120.

The first semiconductor layer 210 and the second semiconductor layer 310 may be made of a polycrystalline semiconductor. For example, polycrystalline semiconductors may be made of, but are not limited to, low temperature poly silicon (LTPS) with high mobility. When the first semiconductor layer 210 and the second semiconductor layer 310 are made of polycrystalline semiconductor, low power consumption power and high reliability may be achieved.

The first semiconductor layer 210 and the second semiconductor layer 310 may be made of an oxide semiconductor. For example, it may be made of, but is not limited to, any one of indium-gallium-zinc-oxide (IGZO), indium-zinc-oxide (IZO), indium-gallium-tin-oxide (IGTO), and indium-gallium-oxide (IGO). When the first semiconductor layer 210 and the second semiconductor layer 310 are made of oxide semiconductors, the effect of blocking leakage current is excellent, and thus the luminance change of the sub-pixel may be minimized during a low-speed operation.

When the first semiconductor layer 210 and the second semiconductor layer 310 are made of a polycrystalline semiconductor or an oxide semiconductor, some regions of the first semiconductor layer 210 and the second semiconductor layer 310 may have conductive regions.

The first semiconductor layer 210 and the second semiconductor layer 310 may also be made of amorphous silicon (a-Si), or may be made of various organic semiconductor materials such as pentacene or the like, but are not limited thereto.

A second insulating layer 130 may be disposed on the first semiconductor layer 210 and the second semiconductor layer 310 over the entire area of the substrate 110.

The second insulating layer 130 may be disposed between the first semiconductor layer 210 and the first gate electrode 230 to insulate the first semiconductor layer 210 and the first gate electrode 230. The second insulating layer 130 may be disposed between the second semiconductor layer 310 and the second gate electrode 330 to insulate the second semiconductor layer 310 and the second gate electrode 330.

The second insulating layer 130 may be formed of an insulating inorganic material, such as silicon nitride (SiNx) or silicon oxide (SiOx), or the like, and may also be formed of an insulating organic material, or the like, and embodiments of the present specification are not limited thereto.

The second insulating layer 130 may include holes for electrically connecting each of the first source electrode 250 and the first drain electrode 270 to the first semiconductor layer 210. The second insulating layer 130 may include holes for electrically connecting each of the second source electrode 350 and the second drain electrode 370 to the second semiconductor layer 310.

The first gate electrode 230 of the first thin-film transistor 200 and the second gate electrode 330 of the second thin-film transistor 300 may be disposed on the second insulating layer 130. The first gate electrode 230 may be disposed to overlap the first semiconductor layer 210. The second gate electrode 330 may be disposed to overlap the second semiconductor layer 310.

A storage capacitor 400 may be disposed on the second insulating layer 130. The storage capacitor 400 may include a first capacitor electrode 410 and a second capacitor electrode 420. The storage capacitor 400 may store the data voltage applied via the data line for a period of time and provide it to the first electrode 510.

The first capacitor electrode 410 of the storage capacitor 400 may be disposed on the second insulating layer 130.

The first gate electrode 230, the second gate electrode 330, and the first capacitor electrode 410 may be disposed on the same layer. For example, the first gate electrode 230, the second gate electrode 330, and the first capacitor electrode 410 may be disposed on the second insulating layer 130.

The first gate electrode 230, the second gate electrode 330, and the first capacitor electrode 410 may be formed by the same process.

The first gate electrode 230, the second gate electrode 330, and the first capacitor electrode 410 may be formed as a single layer or multiple layers made of any one of molybdenum (Mo), copper (Cu), titanium (Ti), aluminum (Al), chromium (Cr), gold (Au), nickel (Ni), neodymium (Nd), tungsten (W), and a transparent conductive oxide (TCO), or alloys thereof, and embodiments of the present specification are not limited thereto.

A third insulating layer 140 may be disposed on the first gate electrode 230, the second gate electrode 330, and the first capacitor electrode 410 over the entire area of the substrate 110.

The third insulating layer 140 may be disposed between the first gate electrode 230, and the first source electrode 250, the first drain electrode 270 to insulate the first gate electrode 230 with the first source electrode 250, and the first drain electrode 270. The third insulating layer 140 may be disposed between the second gate electrode 330, the second source electrode 350, and the second drain electrode 370 to insulate the second gate electrode 330 with the second source electrode 350, and the second drain electrode 370.

The third insulating layer 140 may include holes for electrically connecting each of the first source electrode 250 and the first drain electrode 270 to the first semiconductor layer 210. The third insulating layer 140 may include holes for electrically connecting each of the second source electrode 350 and the second drain electrode 370 to the second semiconductor layer 310.

The third insulating layer 140 may be formed of an insulating inorganic material, such as silicon nitride (SiNx) or silicon oxide (SiOx), or the like, and may also be formed of an insulating organic material, or the like, and embodiments of the present specification are not limited thereto.

The second capacitor electrode 420 of the storage capacitor 400 may be disposed on the third insulating layer 140. The second capacitor electrode 420 may be disposed to overlap the first capacitor electrode 410.

The second capacitor electrode 420 may be formed as a single layer or multiple layers made of any one of molybdenum (Mo), copper (Cu), titanium (Ti), aluminum (Al), chromium (Cr), gold (Au), nickel (Ni), neodymium (Nd), tungsten (W), and transparent conductive oxide (TCO), or alloys thereof, and embodiments of the present specification are not limited thereto.

A fourth insulating layer 150 may be disposed on the second capacitor electrode 420 over the entire area of the substrate 110.

The fourth insulating layer 150 may be disposed between the first gate electrode 230, and the first source electrode 250, the first drain electrode 270 to insulate the first gate electrode 230 with the first source electrode 250, and the first drain electrode 270. The fourth insulating layer 150 may be disposed between the second gate electrode 330, and the second source electrode 350, the second drain electrode 370 to insulate the second gate electrode 330 with the second source electrode 350, and the second drain electrode 370.

The fourth insulating layer 150 may include holes for electrically connecting each of the first source electrode 250 and the first drain electrode 270 to the first semiconductor layer 210. The fourth insulating layer 150 may include holes for electrically connecting each of the second source electrode 350 and the second drain electrode 370 to the second semiconductor layer 310.

The fourth insulating layer 150 may be formed of an insulating inorganic material, such as silicon nitride (SiNx) or silicon oxide (SiOx), or the like, and may also be formed of an insulating organic material, or the like, and embodiments of the present specification are not limited thereto.

The first source electrode 250 and the first drain electrode 270 may be disposed on the fourth insulating layer 150. The second source electrode 350 and the second drain electrode 370 may be disposed on the fourth insulating layer 150.

Each of the first source electrode 250 and the first drain electrode 270 may be electrically connected to the first semiconductor layer 210 via holes in the second insulating layer 130, the third insulating layer 140, and the fourth insulating layer 150. Each of the second source electrode 350 and the second drain electrode 370 may be electrically connected to the second semiconductor layer 310 via holes in the second insulating layer 130, the third insulating layer 140, and the fourth insulating layer 150.

The first source electrode 250, the first drain electrode 270, the second source electrode 350, and the second drain electrode 370 may be formed as a single layer or multiple layers made of any one of molybdenum (Mo), copper (Cu), titanium (Ti), aluminum (Al) chromium (Cr), gold (Au), nickel (Ni), neodymium (Nd), tungsten (W), and transparent conductive oxide (TCO), or alloys thereof, and embodiments of the present specification are not limited thereto. For example, the first source electrode 250, the first drain electrode 270, the second source electrode 350, and the second drain electrode 370 may have a three-layer structure of titanium (Ti)/aluminum (Al)/titanium (Ti) made of a conductive metallic material, and embodiments of the present specification are not limited thereto.

A fifth insulating layer 160 may be disposed on the first source electrode 250, the first drain electrode 270, the second source electrode 350, and the second drain electrode 370 over the entire area of the substrate 110.

The fifth insulating layer 160 may protect the first thin-film transistor 200 and the second thin-film transistor 300. The fifth insulating layer 160 may be formed of an insulating inorganic material, such as silicon nitride (SiNx) or silicon oxide (SiOx), or the like, and may also be formed of an insulating organic material, or the like, and embodiments of the present specification are not limited thereto.

The fifth insulating layer 160 may include holes for electrically connecting the second thin-film transistor 300 to the connection electrode 180 or the first electrode 510. The fifth insulating layer 160 may be omitted depending on the structure and type of the thin-film transistor.

A protective layer 170 may be disposed on the fifth insulating layer 160. For example, the protective layer 170 may be an insulating layer or a planarization layer, and embodiments of the present specification are not limited thereto. The protective layer 170 may protect the thin-film transistor disposed below the protective layer 170, and may mitigate or planarize steps caused by different patterns. For example, the protective layer 170 may insulate components disposed above and below the protective layer 170. For example, although the protective layer 170 may be disposed as a single layer, it may be disposed as multiple layers, such as two or more layers, taking into account the arrangement of the electrodes, and embodiments of the present specification are not limited thereto.

As the display apparatus evolves to higher resolutions, the amount of signal wirings increases, making it difficult to place all of the wirings on one layer while maintaining a minimum distance, so additional layers may be constructed. The additional layers allow for more flexibility in wiring placement, which may make wire/electrode layout design easier. The protective layer 170 may also be used to form capacitance between the metal layers when a dielectric material is used as a planarization layer composed of multiple layers.

When the protective layer 170 is disposed as two layers, it may include a first protective layer 171 and a second protective layer 172. For example, the first protective layer 171 may be a sixth insulating layer, and embodiments of the present specification are not limited thereto. For example, the second protective layer 172 may be a seventh insulating layer, and embodiments of the present specification are not limited thereto. For example, a hole may be formed in the first protective layer 171 and a connection electrode 180 may be disposed in the hole. The second protective layer 172 having the hole may be disposed on the first protective layer 171 and the connection electrode 180. A first electrode 510 may be disposed in the hole of the second protective layer 172. Therefore, the second thin-film transistor 300 and the first electrode 510 may be electrically connected via the connection electrode 180.

One end (or a portion or one side) of the connection electrode 180 may be connected to the second thin-film transistor 300, and the other end (or the other portion or the other side) of the connection electrode 180 may be connected to the first electrode 510.

The connection electrode 180 may also be disposed on the first protective layer 171.

The connection electrode 180 may be formed as a single layer or multiple layers made of any one of molybdenum (Mo), copper (Cu), titanium (Ti), aluminum (Al), chromium (Cr), gold (Au), nickel (Ni), neodymium (Nd), tungsten (W), and transparent conductive oxide (TCO), or alloys thereof, and embodiments of the present specification are not limited thereto. For example, the connection electrode 180 may be a three-layer structure of titanium (Ti)/aluminum (Al)/titanium (Ti) made of a conductive metallic material.

The connection electrode 180 may be a first connection electrode, and embodiments of the present specification are not limited thereto. The connection electrodes 180 may be omitted based on the structure and type of display apparatus.

The second protective layer 172 may be disposed on the first protective layer 171 and the connecting electrode 180.

The first protective layer 171 and the second protective layer 172 may be formed of at least one or more of an organic insulating material such as BCB (BenzoCycloButene), an acrylic resin, an epoxy resin, a phenolic resin, a polyamide resin, or a polyimide resin, and embodiments of the present specification are not limited thereto.

The protective layer 170 of the display apparatus may be arranged as three layers to account for the arrangement of the electrodes, but embodiments of the present specification are not limited thereto.

The light-emitting element layer 500 may be disposed on the protective layer 170 or the second protective layer 172. The light-emitting element layer 500 may include the first electrode 510, an organic layer 540, and a second electrode 550.

The first electrode 510 may be disposed on the protective layer 170. The first electrode 510 may supply holes to the organic layer 540 and may be made of a conductive material having a high work function. The first electrode may be an anode electrode, and embodiments of the present specification are not limited thereto.

When the display apparatus is a top emission display apparatus, the first electrode 510 may be arranged using an opaque conductive material as a reflective electrode that reflects light. The first electrode 510 may be formed of at least one or more of silver (Ag), aluminum (Al), gold (Au), molybdenum (Mo), tungsten (W), chromium (Cr), or an alloy thereof, but embodiments of the present specification are not limited thereto. For example, the first electrode 510 may have a three-layer structure of silver (Ag)/lead (Pd)/copper (Cu), but is not limited thereto. Alternatively, the first electrode 510 may further include a layer of a transparent conductive material with a high work function, such as indium-tin-oxide (ITO).

When the display apparatus is a bottom emission display apparatus, the first electrode 510 may be arranged using a transparent conductive material that transmits light. For example, the first electrode 510 may be formed of at least one or more of indium tin oxide (ITO), indium zinc oxide (IZO), or indium tin oxide (ITO), but embodiments of the present specification are not limited thereto.

A bank 520 may be disposed on the first electrode 510 and the protective layer 170.

The bank 520 may distinguish between a plurality of sub-pixels, minimize light blur and prevent color mixing occurring at different viewing angles. The bank 520 may define (or distinguish) a light-emitting part that emits light and a non-light-emitting part that does not emit light. The bank 520 may be disposed on a non-light-emitting part. The bank 520 may have a bank hole that exposes the light-emitting part and the first electrode 510.

The bank 520 may be made of at least one or more of an inorganic insulating material such as silicon nitride (SiNx) or silicon oxide (SiOx), or an organic insulating material such as benzocyclobutene (BCB), acrylic resin, epoxy resin, phenolic resin, polyamide resin, polyimide resin, or a photosensitizer including a black pigment, and embodiments of the present specification are not limited thereto.

The bank 520 may be formed in black or colored. For example, when the bank 520 includes a black material, external light, internal reflected light, and/or scattered light from the side surface of the first electrode 510 may be prevented from entering the thin-film transistor, which may improve a problem of deterioration of the luminance of the display apparatus. The bank 520 may be disposed to cover an end (or a partial area) of the first electrode 510.

At least one or more spacers 530 may be disposed on the bank 520.

The spacer 530 may prevent damage to the organic layer 540 during processing of the organic layer 540, and may minimize or at least reduce breakage of the display apparatus due to an external impact.

The spacer 530 may be formed of the same material as the bank 520, and may be formed simultaneously with the bank 520, or may be formed in a separate process. For example, the spacer 530 may be transparent, black, or colored. Alternatively, the spacer 530 may include a transparent material or a black material or a colored material, and embodiments of the present specification are not limited thereto.

The thickness of the spacer 530 may be equal to or greater than the thickness of the bank 520, and the thickness of the spacer 530 may be from 1 μm to 2 μm, but embodiments of the present specification are not limited thereto.

An organic layer 540 may be disposed on the first electrode 510 and the bank 520. The organic layer 540 may include an emitting layer (EML) for emitting a specific color of light to each of the plurality of sub-pixels. The emitting layer may be a layer that emits light. For example, holes generated by the first electrode 510 and electrons generated by the second electrode 550 may be injected into the emitting layer. The electrons may combine with holes injected into the emitting layer to create excitons. Light may be generated when the generated excitons fall from an excited state to a ground state.

For example, the emitting layer may include one of a red emitting layer that emits red light, a green emitting layer that emits green light, a blue emitting layer that emits blue light, and a white emitting layer. When the organic layer 540 includes the white emitting layer, a color filter may be disposed on the organic layer 540 for converting white light from the white emitting layer into light of another color. In addition to the emitting layer, the organic layer 540 may further include a hole injection layer (HIL), a hole transport layer (HTL), an electron blocking layer (EBL), a hole blocking layer (HBL), an electron transport layer (ETL), and an electron injection layer (EIL), but embodiments of the present specification are not limited thereto.

The emitting layer of the organic layer 540 may be disposed on each of the plurality of sub-pixels, and at least one or more of the hole injection layer (HIL), the hole transport layer (HTL), the electron barrier layer (EBL), the hole barrier layer (HBL), the electron transport layer (ETL), or the electron injection layer (EIL) of the organic layer 540 may be disposed over the entire display area.

The organic layer 540 of the display apparatus according to the present specification may be an emitting unit. At least one or more light-emitting unit may be disposed. For example, a plurality of light-emitting units may be stacked between the first electrode 510 and the second electrode 550 to form a stacked structure. In this case, a charge generating layer may be further disposed between the plurality of light-emitting units. The light-emitting unit may be disposed in multiple for each sub-pixel.

The light-emitting unit will be described in more detail with reference to FIG. 10.

A second electrode 550 may be disposed on the organic layer 540. The second electrode 550 may supply electrons to the organic layer 540 and may be made of a conductive material having a low work function. The second electrode may be a cathode electrode, and embodiments of the present specification are not limited thereto.

When the display apparatus is a top emission display apparatus, the second electrode 550 may be arranged using a transparent conductive material that transmits light. For example, it may be formed of at least one or more of Indium Tin Oxide (ITO), Indium Zinc Oxide (IZO), or Indium Tin Oxide (ITO), and embodiments of the present specification are not limited thereto. Additionally, the second electrode 550 may be arranged using a translucent conductive material that transmits light. For example, it may be formed of at least one or more of alloys such as LiF/Al, CsF/Al, Mg:Ag, Ca/Ag, Ca:Ag, LiF/Mg:Ag, LiF/Ca/Ag, or LiF/Ca:Ag, and embodiments of the present specification are not limited thereto.

When the display apparatus is a bottom emission display apparatus, the second electrode 550 may be arranged using an opaque conductive material as a reflective electrode that reflects light. For example, the second electrode 550 may be formed of at least one or more of silver (Ag), aluminum (Al), gold (Au), molybdenum (Mo), tungsten (W), chromium (Cr), or an alloy thereof, and embodiments of the present specification are not limited thereto.

An encapsulation part 600 may be disposed on the second electrode 550. The encapsulation part 600 may protect the organic layer 540 from external moisture, oxygen, or debris. For example, external oxygen and moisture may be blocked to prevent oxidation of luminescent materials and electrode materials.

The encapsulation part 600 may include a first encapsulation layer 610, a second encapsulation layer 620, and a third encapsulation layer 630 that prevent the penetration of moisture or oxygen. The first encapsulation layer 610, the second encapsulation layer 620, and the third encapsulation layer 630 may have an alternately stacked structure, but embodiments of the present specification are not limited thereto.

The encapsulation part 600 may be made of a transparent material to allow light emitted from the emitting layer to be transmitted.

The first encapsulation layer 610 and the third encapsulation layer 630 may be made of at least one or more inorganic materials, such as, but not limited to, silicon nitride (SiNx), silicon oxide (SiOx), or aluminum oxide (AlyOz). The first encapsulation layer 610 and the third encapsulation layer 630 may be formed using a vacuum deposition method such as, but not limited to, chemical vapor deposition (CVD) or atomic layer deposition (ALD).

The first encapsulation layer 610 and the third encapsulation layer 630 may be formed in at least two or more layers. For example, the first encapsulation layer 610 may have, but is not limited to, a three-layer structure of silicon oxide (SiOx)/silicon nitride (SiNx)/silicon oxide (SiOx). In other examples, the first encapsulation layer 610 may have, but is not limited to, a four-layer structure of silicon oxide (SiOx)/silicon nitride (SiNx)/silicon oxide (SiOx)/silicon oxide (SiOx).

The second encapsulation layer 620 may cover any debris or particles that may be generated during the manufacturing process. Additionally, the second encapsulation layer 620 may planarize the surface of the first encapsulation layer 610. For example, the second encapsulation layer 620 may be a particle cover layer, and is not limited by terminology.

The second encapsulation layer 620 may be an organic material, e.g., a polymer, such as, but not limited to, a siliconoxycarbon (SiOCz), epoxy, polyimide, polyethylene, or acrylate.

The second encapsulation layer 620 may be made of a thermosetting material or a light-curable material that is cured by heat or light.

The second encapsulation layer 620 may be formed in a variety of ways, such as inkjet coating, or slit coating, and embodiments herein are not limited thereto. For example, a second encapsulation layer 620 may be formed on the first encapsulation layer 610 by spraying or dropping a liquid organic material into the display area on the substrate 110 on which the first encapsulation layer 610 is formed using an inkjet device or a nozzle coating device. As a spray nozzle moves over an application area (or as the spray nozzle is stationary and a target moves), organic material in a fluid state may be formed in the application area.

The material forming the second encapsulation layer 620 may have a low viscosity characteristic and therefore may be in a dense liquid-like state until it is cured. A dam may be disposed to solve the problem of the second encapsulation layer 620 spreading (or flowing) into non-display area.

A touch part 700 may be disposed on the encapsulation part 600.

The touch part 700 may include a first touch electrode 740_R, a first touch connection electrode 720, a second touch electrode, and a second touch connection electrode 740_C.

A portion of the first touch electrode 740_R, the first touch connection electrode 720, the second touch electrode, and the second touch connection electrode 740_C may be disposed to overlap the bank 520.

The first touch electrode 740_R, the second touch electrode, the first touch connection electrode 720, and the second touch connection electrode 740_C may be formed in a mesh pattern of intersecting metal lines. The mesh pattern may have a rhombus shape. Further, the shape of the mesh pattern may be, but is not limited to, a square, pentagon, hexagon, circle, or ellipse.

The first touch electrode 740_R, the second touch electrode, the first touch connection electrode 720, and the second touch connection electrode 740_C may be disposed using a low resistivity, opaque conductive material. For example, it may be formed as a single layer or multiple layers made of any one of, but not limited to, molybdenum (Mo), copper (Cu), titanium (Ti), aluminum (Al) chromium (Cr), gold (Au), nickel (Ni), neodymium (Nd), tungsten (W), and transparent conductive oxide (TCO), or an alloy thereof. For example, the first touch electrode 740_R, the second touch electrode, the first touch connection electrode 720, and the second touch connection electrode 740_C may be made of, but are not limited to, a three-layer structure of a conductive metallic material of titanium (Ti)/aluminum (Al)/titanium (Ti).

The first touch electrode 740_R, the second touch electrode, the first touch connection electrode 720, and the second touch connection electrode 740_C may be made of the same material as the first source electrode 250, the first drain electrode 270, the second source electrode 350, and the second drain electrode 370, but embodiments of the present specification are not limited thereto.

A buffer layer 710 may be disposed on the encapsulation part 600. The buffer layer 710 may prevent chemical liquids (such as developer or etchant) used during the manufacturing process of the touch part 700, or moisture from the outside, from penetrating into the light-emitting element layer 500 including an organic material. In addition, it is possible to prevent a problem of a plurality of touch sensor metals disposed above the buffer layer 710 being broken due to an external impact, and to block interference signals that may occur when the touch part 700 is driven. For example, the buffer layer 710 may be a touch buffer layer, a second buffer layer, or an eighth insulating layer, and embodiments of the present specification are not limited thereto.

The buffer layer 710 may be made of at least one or more of, but not limited to, an inorganic insulating material such as silicon nitride (SiNx) or silicon oxide (SiOx), or an organic insulating material such as benzocyclobutene (BCB), acrylic resin, epoxy resin, phenolic resin, polyamide resin, or polyimide resin.

The first touch connection electrode 720 may be disposed on the buffer layer 710.

For example, the first touch connection electrode 720 may be disposed between adjacent first touch electrodes 740_R in the first direction (or X-axis direction). The first touch connection electrode 720 may electrically connect, but is not limited to, a plurality of first touch electrodes 740_R that are spaced apart from each other in a first direction (or X-axis direction) and that are adjacent to each other.

The first touch connection electrode 720 may be disposed to overlap the second touch connection electrode 740_C, which connects the second touch electrode adjacent in the second direction (or Y-axis direction). The first touch connection electrode 720 and the second touch connection electrode 740_C may be formed in different layers, and thus may be electrically isolated from each other. For example, the first touch connection electrode 720 may be a connection electrode or a second connection electrode, and embodiments of the present specification are not limited thereto. For example, the second touch connection electrode 740_C may be a third connection electrode, and embodiments of the present specification are not limited thereto.

An insulating layer 730 may be disposed on the buffer layer 710 and the first touch connection electrode 720. For example, the insulating layer 730 may be a touch insulating layer or a ninth insulating layer, and embodiments of the present specification are not limited thereto.

The insulating layer 730 may include holes for electrically connecting the first touch electrode 740_R and the first touch connection electrode 720. For example, the insulating layer 730 may electrically isolate the second touch electrode and the second touch connection electrode 740_C from each other. For example, the insulating layer 730 may be made of an organic material, e.g., a polymer, such as, but not limited to, a silicone oxycarbon (SiOCz), epoxy, polyimide, polyethylene, or acrylate. The insulating layer 730 may be made of a thermosetting material or a photocurable material that is cured by heat or light.

When the insulating layer 730 is made of an inorganic material, the insulating layer 730 is disposed along rapid steps and curves of the various components disposed below the insulating layer 730. Thus, the rapid steps and curves may be not covered, which may cause some of the internal components of the display apparatus to be visible from the outside. This is aesthetically unpleasant for users because it is perceived as a defect, such as a stain. In addition, the insulating layer made of inorganic materials is less effective than the insulating layer made of organic materials at blocking moisture and oxygen from entering the display apparatus from the outside. Furthermore, it may not cover debris or particles that may be generated during the manufacturing process. In addition, when the insulating layer 730 is made of organic materials, it is possible to improve the problem of the occurrence of cracks and disconnection of wirings caused by mechanical stress in a bending area during or after the bending process of the plate during the manufacturing process of the display apparatus including the bending area.

The first touch electrode 740_R, the second touch electrode, and the second touch connection electrode 740_C may be disposed on the insulating layer 730.

The first touch electrode 740_R and the second touch electrode may be spaced apart from each other by a predetermined interval. At least one or more first touch electrodes 740_R that are adjacent in the first direction (or X-axis direction) may be formed to be spaced apart from each other. The at least one or more first touch electrodes 740_R adjacent in the first direction (or X-axis direction) may be connected to the first touch connection electrode 720 disposed between the plurality of first touch electrodes 740_R. For example, a plurality of adjacent first touch electrodes 740_R may be connected to the first touch connection electrodes 720 through holes in the insulating layer 730.

The second touch electrodes that are adjacent in the second direction (or Y-axis direction) may be connected by the second touch connection electrode 740_C. The second touch electrode and the second touch connection electrode 740_C may be formed in the same layer. For example, the second touch connection electrode 740_C may be disposed between a plurality of second touch electrodes on the same layer as the second touch electrode. The second touch connection electrode 740_C may be formed extending from the second touch electrode.

The first touch electrode 740_R, the second touch electrode, and the second touch connection electrode 740_C may be formed by the same process.

A protective layer 750 may be disposed on the first touch electrode 740_R, the second touch electrode, and the second touch connection electrode 740_C. For example, the protective layer 750 may be a planarization layer, a touch planarization layer, a tenth insulating layer, or a third protective layer, and embodiments of the present specification are not limited thereto.

The touch driving circuit may receive a touch detection signal from the first touch electrode 740_R. Further, the touch driving circuit may transmit a touch driving signal from the second touch electrode. The touch driving circuit may sense a user's touch by using mutual capacitance between the plurality of first touch electrodes 740_R and the second touch electrode. For example, when a touch action is performed on the display apparatus, a change in capacitance may occur between the first touch electrode 740_R and the second touch electrode. The touch driving circuit may detect touch coordinates by sensing such a change in capacitance.

FIG. 10 is a cross-sectional view of a light-emitting unit according to an embodiment of the present specification. The description of the light-emitting unit shown in FIG. 10 is equally applicable to FIG. 9.

A plurality of light-emitting units 540 may be stacked between the first electrode 510 and the second electrode 550 to form a stack structure. Although FIG. 10 shows two light-emitting units, a plurality of two or more light-emitting units may be configured, and embodiments of the present specification are not limited thereto.

Referring to FIG. 10, a light-emitting unit 540 may include a first light-emitting unit 541, a second light-emitting unit 542, and a charge generation layer (CGL) 60 may be further disposed between the plurality of light-emitting units. For example, the charge generating layer 60 may be disposed between the first light-emitting unit 541 and the second light-emitting unit 542.

A light-emitting element layer composed of a plurality of light-emitting units may have a higher light-emitting efficiency and a longer lifetime than a light-emitting element layer composed of a single organic layer or a single light-emitting unit. For example, by connecting a plurality of light-emitting units in series to meet the conditions of the amount of light emission or the intensity of light emission required by the display apparatus, the stress, resistance, current concentration, or deterioration of a single organic layer or a single light-emitting unit may be distributed, thereby increasing the efficiency and lifetime of each light-emitting unit and improving the reliability of the display apparatus.

The charge generation layer (CGL) 60 may be disposed between the plurality of light-emitting units to regulate the charge balance. The charge generating layer may include an N-type charge-generating layer (N-CGL) and a P-type charge-generating layer (P-CGL). The N-type charge generating layer (N-CGL) serves to inject electrons into the light-emitting unit, and the N-type charge-generating layer (N-CGL) may be made of, but is not limited to, an organic layer doped with an alkali metal such as lithium (Li), sodium (Na), potassium (K), or cesium (Cs), or an alkaline earth metal such as magnesium (Mg), strontium (Sr), barium (Ba), or radium (Ra). The P-type charge generating layer (P-CGL) serves to inject holes into the light-emitting unit. The P-type charge generating layer (P-CGL) may be formed of, but is not limited to, an organic layer containing a P-type dopant.

The pixel disposed in a display area AA of the present specification may further include a plurality of sub-pixels SP-1, SP-2, SP-3. Each of the sub-pixels SP-1, SP-2, SP-3 may be an individual unit that emits light, and a plurality of sub-pixels may include, but are not limited to, red, green, blue, and/or white sub-pixels.

A first sub-pixel SP-1), a second sub-pixel SP-2, and a third sub-pixel SP-3 may emit different colors of light, and the first sub-pixel SP-1, the second sub-pixel SP-2, and the third sub-pixel SP-3 may emit at least one of the red light, green light, or blue light. The first sub-pixel SP-1 is described herein as emitting red light, the second sub-pixel SP-2 as emitting green light, and the third sub-pixel SP-3 as emitting blue light.

The first light-emitting unit 541 may be disposed on the first electrode 510. The first light-emitting unit 541 may include a first hole transport layer (HTL) 51, a first emitting layer (EML) 52, and a first electron transport layer (ETL) 53. The first light-emitting unit 541 may further include a hole injection layer (HIL) and/or an electron barrier layer (EBL), wherein the hole injection layer (HIL) and the electron barrier layer (EBL) may be disposed between the first electrode 510 and the first hole transport layer (HTL) 51.

The hole injection layer (HIL) may be disposed on the first electrode 510. The hole injection layer (HIL) may serve to facilitate the injection of holes from the first electrode 510 into the first hole transport layer (HTL) 51.

The first hole transport layer (HTL) 51 may be disposed on the first electrode 510 or hole injection layer (HIL). The first hole transport layer (HTL) 51 may supply holes from the first electrode 510 or the hole injection layer (TIL) to the first emitting layer (EML) 52. The first hole transport layer (HTL) 51 may be formed by applying two or more layers or two or more materials.

The first emitting layer (EML) 52 may be disposed on the first hole transport layer (HTL) 51. The first emitting layer (EML) 52 may generate light due to the recombination of holes supplied through the first hole transport layer (HTL) 51 and electrons supplied through the first electron transport layer (ETL) 53. The first emitting layer (EML) 52 may further include a first auxiliary emitting layer above or below the first emitting layer (EML) 52.

The first emitting layer (EML) 52 may have a different emitting layer disposed for each sub-pixel. For example, the emitting layer (EML) 52 may include a first red emitting layer 52-R, a first green emitting layer 52-G, and a first blue emitting layer 52-B.

The first red emitting layer 52-R located in the first sub-pixel SP-1 may emit red light. The wavelength region of the light emitted by the first red emitting layer 52-R may be in the range of 640 nm to 700 nm.

The first green emitting layer 52-G located in the second sub-pixel SP-2 may emit green light. The wavelength region of the light emitted by the first green emitting layer 52-G may be in the range of 510 nm to 580 nm.

The first blue emitting layer 52-B located in the third sub-pixel SP-3 may emit blue light. The wavelength region of the light emitted by the first blue emitting layer 52-B may be in the range of 440 nm to 480 nm.

The first emitting layer (EML) 52 may comprise at least one host and a dopant. Alternatively, the first emitting layer (EML) 52 may comprise a mixed host of two or more hosts and at least one dopant. The mixed host may include hosts having hole transport properties and hosts having electron transport properties. When configured as a mixed host, the charge balance of the emitting layer may be regulated to improve the efficiency of the emitting layer. The dopant may comprise a fluorescent dopant or a phosphorescent dopant.

The first electron transport layer ETL 51 may be disposed on the first light emitting layer EML 52. The first electron transport layer (ETL) 51 may supply electrons received from the first charge generating layer 61 to the first emitting layer (EML) 52. Thus, in the first emitting layer (EML) 52, light may be generated due to the recombination of holes supplied through the first hole transport layer (HTL) 51 and electrons supplied through the first electron transport layer (ETL) 53.

The first electron transport layer (ETL) 53 may be formed by applying two or more layers or two or more materials. An electron injection layer (EIL) may be further formed on the first electron transport layer (ETL) 53.

An electron blocking layer (EBL) and a hole blocking layer (HBL) may be further included to improve the efficiency of the first emitting layer (EML) 52. The electron blocking layer (EBL) may be disposed between the first hole transport layer (HTL) 51 and the first emitting layer (EML) 52, and the hole blocking layer (HBL) may be disposed between the first electron transport layer (ETL) 53 and the first emitting layer (EML) 52.

The charge generation layer 60 may be disposed on the first light emitting unit 541. The charge generating layer 60 may include an N-type charge generating layer (N-CGL) that supplies electrons to the first light-emitting unit 541 and a P-type charge generating layer (P-CGL) that supplies holes to the second light-emitting unit 542. The N-type charge-generating layer (N-CGL) may be disposed adjacent to the first light-emitting unit 541, and the P-type charge-generating layer (P-CGL) may be disposed adjacent to the second light-emitting unit 542. For example, an N-type charge generating layer (N-CGL) may be disposed on the first light-emitting unit 541 and a P-type charge generating layer (P-CGL) may be disposed on the N-type charge generating layer (N-CGL).

The second light-emitting unit 542 may be disposed on the charge generation layer 60. The second light-emitting unit 542 may include a second hole transport layer (HTL) 54, a second emitting layer (EML) 55, and a second electron transport layer (ETL) 56. The second light-emitting unit 542 may further include a hole injection layer (HIL) and/or an electron blocking layer (EBL), and the hole injection layer (HIL) and the electron blocking layer (EBL) may be disposed between the charge generating layer 60 and the second hole transport layer (HTL) 54.

The second hole transport layer (HTL) 54 may be disposed on the charge generating layer 60. The second hole transport layer (HTL) 54 may supply holes from the P-type charge generating layer (P-CGL) of the charge generating layer 60 to the second emitting layer (EML) 55. The second hole transport layer (HTL) 54 may be formed by applying two or more layers or two or more materials.

The second emitting layer (EML) 55 may be disposed on the first hole transport layer (HTL) 54. The second emitting layer (EML) 55 may generate light due to the recombination of holes supplied through second hole transport layer (HTL) 54 and electrons supplied through the second electron transport layer (ETL) 56.

The second emitting layer (EML) 55 may have a different emitting layer disposed for each sub-pixel. For example, the second emitting layer (EML) 55 may include a second red emitting layer 55-R, a second green emitting layer 55-G, and a second blue emitting layer 55-B.

The second red emitting layer 55-R located in the first sub-pixel SP-1 may emit red light. The wavelength region of the light emitted by the second red emitting layer 55-R may be in the range of 600 nm to 700 nm.

The second green emitting layer 55-G located in the second sub-pixel (SP-2) may emit green light. The wavelength region of the light emitted by the second green emitting layer 55-B may be in the range of 510 nm to 590 nm.

The second blue emitting layer 55-B located in the third sub-pixel SP-3 may emit blue light. The wavelength region of the light emitted by the second blue emitting layer 55-B may be in the range of 440 nm to 480 nm. The second emitting layer (EML) 55 may further include a second auxiliary emitting layer over or below the second emitting layer (EML) 55.

The second emitting layer (EML) 55 may comprise at least one host and a dopant. Alternatively, the second emitting layer (EML) 55 may comprise a mixed host of two or more hosts and at least one dopant. The mixed host may include hosts having hole transport properties and hosts having electron transport properties. When configured as a mixed host, the charge balance of the emitting layer may be regulated to improve the efficiency of the emitting layer. The dopant may comprise a fluorescent dopant or a phosphorescent dopant.

The second electron transport layer ETL 56 may be disposed on the second light emitting layer EML 55. The second electron transport layer (ETL) 56 may supply electrons received from the second charge generating layer 62 to the second emitting layer (EML) 55. Thus, in the second emitting layer (EML) 55, light may be generated due to the recombination of holes supplied through the second hole transport layer (HTL) 54 and electrons supplied through the second electron transport layer (ETL) 56.

The second electron transport layer (ETL) 56 may be formed by applying two or more layers or two or more materials. The electron implantation layer (EIL) may further be configured on the second electron transport layer (ETL) 56.

An electron blocking layer (EBL) and a hole blocking layer (HBL) may be further included to improve the efficiency of the second emitting layer (EML) 55. The electron barrier layer (EBL) may be disposed between the second hole transport layer (HTL) 54 and the second emitting layer (EML) 55, and the hole blocking layer (HBL) may be disposed between the second electron transport layer (ETL) 55 and the second emitting layer (EML) 55.

The display apparatus according to one or more embodiments of the present specification may be described as follows.

According to an embodiment of the present specification, a display apparatus may include: a display panel configured to display an image; a plate disposed on a rear surface of the display panel; a heat dissipation member disposed on a rear surface of the plate and having a first hole; and an adhesive member disposed between the plate and the heat dissipation member and having a second hole, wherein the heat dissipation member includes a body part and a pattern part.

In the display apparatus according to one or more embodiments of the present specification, the first hole and the second hole may be overlapped with each other, and the diameter of the first hole may be smaller than the diameter of the second hole.

In the display apparatus according to one or more embodiments of the present specification, the pattern part may include a mesh pattern.

In the display apparatus according to one or more embodiments of the present specification, the pattern may be contracted or relaxed by a load applied to the pattern part.

In the display apparatus according to one or more embodiments of the present specification, the pattern part may be configured to overlap the adhesive member.

In the display apparatus according to one or more embodiments of the present specification, the pattern part may further include a protrusion protruding from the adhesive member, and the protrusion may be configured to overlap the second hole of the adhesive member.

In the display apparatus according to one or more embodiments of the present specification, the protrusion may be configured to be at an angle with the adhesive member.

In the display apparatus according to one or more embodiments of the present specification, the angle between the protrusion and the adhesive member may be greater than or equal to 95 degrees and less than or equal to 179 degrees.

In the display apparatus according to one or more embodiments of the present specification, the display apparatus may further comprise an optical device disposed in the first hole.

In the display apparatus according to one or more embodiments of the present specification, the optical device may be disposed on the plate, and the pattern part may be configured to surround the optical device.

In the display apparatus according to one or more embodiments of the present specification, the pattern part may include a first pattern area extending from the body part to be in contact with the adhesive member, and a second pattern area extending from the first pattern area.

In the display apparatus according to one or more embodiments of the present specification, the second pattern area may be configured to overlap the second hole, and the diameter of the first hole may be smaller than the diameter of the second hole.

In the display apparatus according to one or more embodiments of the present specification, with respect to the rear surface of the display panel, the first pattern area may be spaced apart by a first interval, and an end of the second pattern area may be spaced apart by a second interval, and the second interval may be larger than the first interval.

In the display apparatus according to one or more embodiments of the present specification, the second pattern area may be configured to overlap the second hole, the diameter of the first hole may be the same as the diameter of the second hole, and the second pattern area may be smaller than the diameter of the second hole and be spaced apart from a partial area of the adhesive member disposed between the rear surface of the display panel and the second pattern area.

In the display apparatus according to one or more embodiments of the present specification, an end of the second pattern area may be bent to be away from the adhesive member.

According to one or more embodiments of the present specification, a display apparatus may comprise: a display panel configured to display an image; a plate disposed on a rear surface of the display panel; a heat dissipation member disposed on a rear surface of the plate and having a first hole; and an adhesive member disposed between the plate and the heat dissipation member and having a second hole, wherein the heat dissipation member includes a body part and a protrusion extending from the body part and having the first hole, and the protrusion is configured to overlap the second hole.

In the display apparatus according to one or more embodiments of the present specification, the first hole and the second hole may be overlapped with each other, and the diameter of the first hole is smaller than the diameter of the second hole.

In the display apparatus according to one or more embodiments of the present specification, the protrusion may be configured to be at an angle with the adhesive member.

In the display apparatus according to one or more embodiments of the present specification, the angle between the protrusion and the adhesive member may be greater than or equal to 95 degrees and less than or equal to 179 degrees.

In the display apparatus according to one or more embodiments of the present specification, the protrusion may further include a pattern having a mesh shape.

In the display apparatus according to one or more embodiments of the present specification, the pattern may be contracted or relaxed by a load applied to the pattern.

In the display apparatus according to one or more embodiments of the present specification, the display apparatus may further comprise an optical device disposed in the first hole.

In the display apparatus according to one or more embodiments of the present specification, the optical device may be disposed on the plate, and the protrusion may be configured to surround the optical device.

In the display apparatus according to one or more embodiments of the present specification, the display panel may further include a thin-film transistor and a light-emitting element layer, and the light-emitting element layer may include an organic or inorganic material.

In the display apparatus according to one or more embodiments of the present specification, the light-emitting element layer may include a plurality of light-emitting parts and a charge generating layer between the plurality of light-emitting parts.

The display apparatus according to one or more embodiments of the present specification may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation device, an in-vehicle navigation device, an in-vehicle display apparatus, an in-vehicle device, theater device, theater display apparatus, a television, a wallpaper device, a signage device, a gaming device, a laptop, a monitor, a camera, a camcorder, and a home appliance. Further, the display apparatus according to one or more embodiments of the present specification may be applicable to an organic light-emitting illumination device or an inorganic light-emitting illumination device.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### DESCRIPTION OF REFERENCE NUMERALS

| | |
|---|---|
| 3: Adhesive member | 5: Heat dissipation member |
| 3H: Second hole | 5H: First hole |

What is claimed is:

1. A display apparatus comprising:
a display panel configured to display an image;
a plate on a rear surface of the display panel;
a heat dissipation member on a rear surface of the plate, the heat dissipation member having a first hole; and
an adhesive member between the plate and the heat dissipation member, the adhesive member having a second hole,
wherein the heat dissipation member includes a body part and a pattern part.

2. The display apparatus of claim 1, wherein the first hole and the second hole are overlapped with each other, and a diameter of the first hole is smaller than a diameter of the second hole.

3. The display apparatus of claim 1, wherein the pattern part includes a mesh pattern.

4. The display apparatus of claim 3, wherein the mesh pattern contracts or relaxes by a load applied to the pattern part.

5. The display apparatus of claim 1, wherein the pattern part overlaps the adhesive member.

6. The display apparatus of claim 1, wherein the pattern part further includes a protrusion protruding from the adhesive member, and the protrusion overlaps the second hole of the adhesive member.

7. The display apparatus of claim 6, wherein the protrusion is at an angle with the adhesive member.

8. The display apparatus of claim 7, wherein the angle is at least 95 degrees and 179 degrees or less.

9. The display apparatus of claim 1, further comprising:
an optical device in the first hole.

10. The display apparatus of claim 9, wherein the optical device is on the plate, and the pattern part surrounds the optical device.

11. The display apparatus of claim 1, wherein the pattern part includes:
a first pattern area extending from the body part and in contact with the adhesive member; and
a second pattern area extending from the first pattern area.

12. The display apparatus of claim 11, wherein the second pattern area overlaps the second hole, and a diameter of the first hole is less than a diameter of the second hole.

13. The display apparatus of claim 12, wherein with respect to the rear surface of the display panel, the first pattern area is spaced apart by a first interval, and an end of the second pattern area is spaced apart by a second interval, and
the second interval is larger than the first interval.

14. The display apparatus of claim 11, wherein the second pattern area overlaps the second hole,
a diameter of the first hole is a same as a diameter of the second hole, and
the second pattern area is smaller than the diameter of the second hole and is spaced apart from a partial area of the adhesive member that is between the rear surface of the display panel and the second pattern area.

15. The display apparatus of claim 14, wherein an end of the second pattern area is bent away from the adhesive member.

16. A display apparatus comprising:
a display panel configured to display an image;
a plate on a rear surface of the display panel;
a heat dissipation member on a rear surface of the plate, the heat dissipation member having a first hole; and
an adhesive member between the plate and the heat dissipation member, the adhesive member having a second hole,
wherein the heat dissipation member includes a body part and a protrusion extending from the body part and having the first hole, and the protrusion overlaps the second hole.

17. The display apparatus of claim 16, wherein the first hole and the second hole overlap, and a diameter of the first hole is smaller than a diameter of the second hole.

18. The display apparatus of claim 16, wherein the protrusion is at an angle with the adhesive member.

19. The display apparatus of claim 18, wherein the angle is at least 95 degrees and 179 degrees or less.

20. The display apparatus of claim 16, wherein the protrusion further includes a pattern having a mesh shape.

21. The display apparatus of claim 20, wherein the pattern contracts or relaxes by a load applied to the pattern.

22. The display apparatus of claim 16, further comprising:
an optical device in the first hole.

23. The display apparatus of claim 22, wherein the optical device is on the plate, and the protrusion surrounds the optical device.

24. The display apparatus of claim 16, wherein the display panel further includes a thin-film transistor and a light-emitting element layer, and
the light-emitting element layer includes an organic or inorganic material.

25. The display apparatus of claim 24, wherein the light-emitting element layer includes:
a plurality of light-emitting parts; and
a charge generating layer between the plurality of light-emitting parts.
